(19) United States
(12) Patent Application Publication
(10) Pub. No.: US 2024/0240509 A1
(43) Pub. Date: Jul. 18, 2024

(54) SPACER WITH MOISTURE BARRIER

(71) Applicant: SAINT-GOBAIN GLASS FRANCE, COURBEVOIE (FR)

(72) Inventors: Florian CARRE, HERZOGENRATH (DE); Jan HAGEN, HERZOGENRATH (DE); Walter SCHREIBER, HERZOGENRATH (DE)

(21) Appl. No.: 18/559,476

(22) PCT Filed: Aug. 17, 2022
(86) PCT No.: PCT/EP2022/072974

§ 371 Date: Nov. 7, 2023

(30) Foreign Application Priority Data
Aug. 23, 2021 (EP) 21192568.0

(51) Int. Cl. E06B 3/663; B32B 27/08; B32B 27/32; B32B 27/36; C23C 16/34; C23C 16/40; C23C 16/455

(52) U.S. Cl. CPC E06B 3/66333; B32B 27/08; B32B 27/32; B32B 27/36; C23C 16/345; C23C 16/401; C23C 16/403; C23C 16/405; C23C 16/45555; B32B 2255/10; B32B 2255/20; B32B 2255/28; E06B 3/66352; E06B 3/66361

(57) ABSTRACT

A spacer for insulation glass units, includes a polymeric hollow profile including first and second side walls arranged parallel thereto, a glazing interior wall connecting the side walls to one another; an outer wall substantially parallel to the glazing interior wall and connecting the side walls to one another; a cavity enclosed by the side walls, the glazing interior wall and the outer wall, a moisture barrier on the first side wall, the outer wall and on the second side wall of the polymeric hollow body, wherein the moisture barrier includes a first barrier layer and a directly adjacent second barrier layer which are both deposited via atomic layer deposition, the first and second barrier layers each have a thickness of at most 15 nm and are based independently of one another on a nitride, oxidic, sulfidic or fluoridic compound.

The invention relates to a spacer for insulation glass units, to an insulation glass unit and to the use thereof.

Insulating glazings generally contain at least two panes made of glass or of polymeric materials. The panes are separated from one another by a gas or vacuum space defined by the spacer. The thermal insulation capability of insulation glass is significantly higher than that of single glazing and can be even further increased and improved in triple glazings or with special coatings. For example, silver-containing coatings enable reduced transmission of infrared radiation and thus reduce the cooling of a building in winter.

In addition to the nature and structure of the glass, the further components of an insulating glazing are also of great importance. The seal and above all the spacer greatly influence the quality of the insulating glazing. In insulating glazing, a circumferential spacer is fastened between two glass panes so that a gas-filled or air-filled inner pane interspace is produced, which is sealed against the penetration of moisture.

The thermally insulating properties of insulating glazings are substantially influenced by the thermal conductivity in the region of the edge composite, in particular of the spacer. In the case of metallic spacers, the high thermal conductivity of the metal results in the formation of a thermal bridge at the edge of the glass. On the one hand, this thermal bridge leads to heat losses in the edge region of the insulating glazing and, on the other hand, with high air humidity and low external temperatures, to the formation of condensate on the inner pane in the region of the spacer. In order to solve these problems, thermally optimized, so-called “warm-edge” systems are increasingly used, in which the spacers consist of materials of lower thermal conductivity, in particular plastics.

In particular, spacers based on plastic main bodies require an additional seal in order to prevent the loss of a gas filling from the inner pane interspace and the penetration of moisture into the inner pane interspace or to prevent these as far as possible. One possibility for this is, for example, the application of thin metallic films made of aluminum or stainless steel. Disadvantages of pure metallic films are the high material costs and the high thermal conductivity of metals. Since the spacer is part of the edge composite of the insulating glazing, the lowest possible heat conduction through the spacer is sought, in order to prevent the formation of a thermal bridge.

Improved results are achieved by the use of multilayer films which comprise both metallic and polymeric layers, as disclosed for example in WO 2013/104507 A1. Here, several metallic or ceramic layers are preferably used which are arranged alternately with polymeric layers in order to obtain particularly good sealing with simultaneously low heat conduction. The layers are preferably produced by vapor deposition.

For this purpose, document EP2719533 A1 discloses a spacer with a film that has a thin adhesive layer of SiOx or AlOy on the side facing the secondary sealant. The layer can be applied via various methods, for example in a vacuum process (sputtering, evaporation or plasma CVD) or by a reactive gas phase process (plasma CVD or ALD). Apart from the thin adhesive layer, the film contains substantially polymeric layers which assume the moisture-sealing function. Oriented EVOH layers serve, in particular, as the barrier layer against moisture. Moreover, the attachment of a further metal oxide layer between two polymeric layers is disclosed. One disadvantage of EVOH layers is the higher costs compared to commercially available PET layers.

The use of ALD as a method for producing thin layers on polymeric substrates is disclosed, for example, in EP1629543 B1. In particular, it is disclosed here how electronic components can be packaged in an oxygen-tight manner using individual layers up to 100 nm thick. Furthermore, WO 03008110 A1 discloses the application of inorganic layers up to 100 nm thick to organic polymers.

The barrier layers made of metal, metal oxide or certain polymers are decisive for the tightness of a multilayer film. In order to achieve high tightness and at the same time low heat conduction, several layers made of metal or metal oxide are usually used. It is desirable to reduce the number and thickness of the barrier layers in order to keep the material outlay and thus the cost outlay as low as possible.

It is the object of the present invention to provide an improved spacer that does not have the above-mentioned disadvantages, and to provide an improved insulation glass unit.

The object of the present invention is achieved according to the invention by a spacer for insulation glass units according to independent Claim 1. Preferred embodiments of the invention emerge from the dependent claims.

An insulation glass unit according to the invention and its use emerge from further independent claims.

The spacer according to the invention for insulation glass units comprises at least one polymeric hollow profile with a first side wall, a second side wall arranged parallel thereto, a glazing interior wall, an outer wall and a cavity. The cavity is enclosed by the side walls, the glazing interior wall and the outer wall. The glazing interior wall is arranged here substantially perpendicular to the side walls and connects the first side wall to the second side wall. The side walls are the walls of the hollow profile to which the outer panes of the insulation glass unit are attached. The glazing interior wall is the wall of the hollow profile that faces the inner pane interspace after installation into the finished insulation glass unit. The outer wall is arranged substantially parallel to the glazing interior wall and connects the first side wall to the second side wall. After installation in the finished insulation glass unit, the outer wall faces the outer pane interspace.

The spacer further comprises a moisture barrier on the outer wall, the first side wall and the second side wall of the polymeric hollow profile. The moisture barrier seals the inner pane interspace against the penetration of moisture and prevents the loss of a gas contained in the inner pane interspace. The moisture barrier comprises at least one first barrier layer and one second barrier layer, both of which are deposited by atomic layer deposition. The first barrier layer and the second barrier layer directly adjoin one another, i.e. they are in direct contact with one another. There is therefore no further layer, such as an adhesive layer or a layer made of a polymeric material, between the first barrier layer and the second barrier layer. The first barrier layer and the second barrier layer each have a thickness of at most 15 nm. As a result of the embodiment as a “double layer” formed from two directly adjacent layers, a surprisingly good barrier effect with respect to the penetration of moisture is achieved, even though the individual layers are comparatively thin. The first barrier layer and the second barrier layer are based independently of one another on a nitride, oxidic, sulfidic or fluoridic compound. These materials can be used as particularly dense layers via ALD (Atomic Layer Deposition). In comparison with elementary metal layers, these materials are distinguished by a lower thermal conductivity, which is advantageous for the thermally insulating properties of the spacer. The moisture barrier can contain further layers such as barrier layers, polymeric layers or adhesive layers.

If a layer is formed “on the basis of” a material or “based on” a material, the layer consists predominantly of this material, in particular substantially of this material, in addition to any impurities or doping. The proportion of the material is more than 50 wt. %, preferably more than 70 wt. %, particularly preferably more than 90 wt. %, very particularly preferably more than 95 wt. %. ALD (Atomic Layer Deposition) is a method for separating thin layers up to atomic monolayer. The constituents (atoms) of the material to be deposited are bound in chemical form to a carrier gas (so-called precursors and reactants). The particular precursor is chemically bonded to the surface to be coated, wherein a thin layer, usually a monolayer, is bonded to the surface. Subsequently, the reaction chamber is emptied and filled with a reactant. At a defined temperature, a reaction between the bound precursor and the reactant takes place so that a layer of the desired compound is formed on the surface to be coated. The reaction products are then pumped off and the process is started again from the beginning by again introducing the precursor into the reaction chamber. Individual layers are thus applied successively until the desired layer thickness is achieved. Between the individual separation steps, the reaction chamber can be purged with an inert gas, for example argon. Characteristic of ALD is the self-limiting character of the partial reactions: the reactant and the precursor do not react with themself or ligands of themself, which limits the layer growth of a partial reaction for any length of time and any gas quantity to a maximum of one monolayer. Thus, very dense layers with precisely adjusted layer thickness can be produced. Since the gas is distributed uniformly in the reaction chamber, the objects are completely coated irrespective of their geometric shape, apart from any bearing surfaces. Suitable precursors and reactants are known to a person skilled in the art and are published, for example, in M. Leskela and M. Ritala, “ALD precursor chemistry: Evolution and future challenges” in Journal de Physique IV, vol. 9, 837-852 (1999) or in WO 03008110A1 and the references indicated therein.

In a preferred embodiment, the first barrier layer and/or the second barrier layer is a nitride barrier layer. For the generation of nitride ALD coatings, ammonia (NH₃) can, for example, be used as a reactant. Suitable precursors are the corresponding halides, such as, for example, a metal halide. Preferred nitrides are the nitrides of titanium, zirconium, hafnium, vanadium, niobium, tantalum, chromium, molybdenum, tungsten, iron, cobalt, nickel, boron, aluminum, gallium, indium, silicon, and tin. These nitrides can be deposited well via ALD. Particular preference is given to nitrides of boron, silicon, titanium, zirconium, hafnium and aluminum and mixtures thereof. Barrier layers with these nitrides have a particularly high leak tightness. The nitrides can be formed stoichiometrically, sub-stoichiometrically or super-stoichiometrically. The nitrides are preferably formed stoichiometrically, which is possible by the deposition of monolayers by means of atomic layer deposition. For example, Si₃N₄, TiN, ZrN, HfN, AlN are preferred.

In a further preferred embodiment, the first barrier layer and/or the second barrier layer is an oxidic barrier layer. To produce ALD coatings made of a metal oxide, suitable precursors are, for example, the corresponding methyl-metal compound or the corresponding metal chloride on the one hand and, as reactants, water vapor or ozone on the other hand. Preferred oxides are the oxides of magnesium, calcium, strontium, barium, scandium, yttrium, titanium, zirconium, hafnium, vanadium, niobium, tantalum, chromium, molybdenum, tungsten, manganese, iron, cobalt, nickel, zinc, aluminum, gallium, indium, silicon, germanium, tin, and bismuth. Oxides of aluminum, chromium, silicon, titanium, zirconium, hafnium, and mixtures thereof are particularly preferred. The oxides can be formed stoichiometrically, sub-stoichiometrically or super-stoichiometrically. The oxides are preferably formed stoichiometrically, which is possible by the deposition of monolayers by means of atomic layer deposition. For example, Al₂O₃, Cr₂O₃, SiO₂, TiO₂, ZrO₂, HfO₂, or Al₂TiO₅ are preferred.

In a further preferred embodiment, the first barrier layer and/or the second barrier layer is a sulfidic barrier layer. To produce sulfidic ALD coatings, hydrogen sulfide (H₂S), for example, can be used as a reactant. Suitable precursors are the corresponding halides, such as, for example, a metal halide. Preferred sulfides are those of titanium, molybdenum, tungsten, manganese, iron, cobalt, nickel, zinc, aluminum, gallium, indium, germanium, tin, and bismuth. Particularly preferred are the sulfides of iron and cobalt. The sulfides may be stoichiometric, sub- or super-stoichiometric. The sulfides are preferably formed stoichiometrically, which is possible by the deposition of monolayers by means of atomic layer deposition.

In a further preferred embodiment, the first barrier layer and/or the second barrier layer is a fluoridic barrier layer. Preferred are fluorides of lithium, sodium, potassium, rubidium, cesium, magnesium, calcium, strontium, barium, zinc, and aluminum. Particularly preferred are fluorides of magnesium, calcium, strontium, barium. The fluorides can be formed stoichiometrically, sub-stoichiometrically or super-stoichiometrically. The fluorides are preferably formed stoichiometrically, which is possible by the deposition of monolayers by means of atomic layer deposition.

In a further preferred embodiment, the first barrier layer is applied directly to the polymeric hollow profile. The direct application means that the first barrier layer is applied directly to ALD on the polymeric hollow profile so that no adhesive layer or polymeric layer is arranged there. A pretreatment of the polymeric hollow profile with a solvent, a plasma activation, or the like is possible. However, no adhesive layer is provided in the case of the direct application. The second barrier layer is arranged directly adjacent to the first barrier layer. A great advantage of applying a coating with the aid of ALD is that even complicated geometries with dense defined layers are uniformly coated. Preferably, no polymeric layers are applied to the polymeric hollow profile so that the moisture barrier in this case comprises only barrier layers which are preferably all applied via ALD.

In a further preferred embodiment, the moisture barrier in the form of a film is attached to the polymeric hollow profile via an adhesive. In this case, the moisture barrier comprises at least one polymeric layer on which the barrier layers are applied. The coating of films with barrier layers via ALD takes place independently of the production of the polymeric hollow profile. This allows flexible adaptation of the production of spacers with different requirements by replacing the film. Preferably, the moisture barrier is adhered to the polymeric hollow profile by means of a non-gaseous adhesive. The difference in the length extent between the moisture barrier and the polymeric hollow profile can lead to thermal stresses. By attaching the moisture barrier via an adhesive, any stresses can be absorbed via the elasticity of the adhesive. Suitable adhesives are thermoplastic adhesives, but also reactive adhesives, such as multi-component adhesives. Preferably, a thermoplastic polyurethane or a polymethacrylate is used as the adhesive. This has proven to be particularly suitable in tests.

The moisture barrier preferably comprises at least two polymeric layers, preferably exactly two, three or four polymeric layers, particularly preferably two or three polymeric layers. The polymeric layers serve firstly as carrier material and as intermediate layers between the barrier layers

In a further preferred embodiment, the moisture barrier does not comprise any barrier layers based on an elemental metal. Preferably, the moisture barrier comprises exclusively inorganic barrier layers based on nitride, oxidic, sulfidic, or fluoridic compound. Elemental metals, on the other hand, have a relatively high thermal conductivity, which is disadvantageous for the thermally insulating properties of the spacer.

In a further preferred embodiment, a polymeric layer contains polyethylene terephthalate (PET), polyvinylidene chloride (PVdC), polyamides (PA), polyethylene (PE), polypropylene (PP), oriented polypropylene (oPP), biaxially oriented polypropylene (boPP), oriented polyethylene terephthalate (oPET), biaxially oriented polyethylene terephthalate (boPET). Preferably, the polymeric layer or each polymeric layer is formed on the basis, in each case, of one of the polymers mentioned. The polymers mentioned are particularly suitable for coating with ALD and suitable as films for spacers of insulating glazings. The polymeric layer particularly preferably contains PET, oPP, boPP, oPET or boPET, which can be coated particularly well with ALD and can have good adhesion properties to the barrier layers. Oriented polypropylene and oriented polyethylene terephthalate are drawn in one direction. Films made of boPP and boPET are drawn in the longitudinal direction and in the transverse direction. Due to the drawing, the films are more resistant than the original films.

In a further preferred embodiment, the polymeric layer or all polymeric layers has/have a thickness of 5 μm to 50 μm, preferably of 10 μm to 35 μm, particularly preferably of 12 μm to 25 μm. In these regions, the individual layers can be processed well and are obtainable cost-effectively.

In a further preferred embodiment, the moisture barrier does not contain any polymeric layer based on ethylene vinyl alcohol (EVOH). EVOH layers themselves serve as moisture barrier layers, but are relatively cost-intensive and, depending on the thickness of the layer, less dense than inorganic barrier layers. The advantage of the moisture barrier according to the invention is the particularly thin design of the barrier layers, which nevertheless provide high tightness, so that no EVOH layers are required as an additional barrier.

In a further preferred embodiment, the moisture barrier contains at least three barrier layers, preferably at least four barrier layers, further preferably at least five barrier layers or at least six barrier layers. The moisture barrier preferably contains exactly three, four, five or six barrier layers. It has been shown that a higher number of thin barrier layers leads to a significant improvement in the tightness, while the increase in the thickness of the barrier layers results in only a slight improvement in the tightness.

Preferably, all barrier layers are deposited by means of atomic layer deposition and are based independently of one another on a nitride, oxidic, sulfidic or fluoridic compound. Due to the use of ALD for producing the barrier layers, many thin layers can be used. The use of a single method for producing a moisture barrier additionally simplifies the production process.

In an alternative preferred embodiment, conventional methods such as CVD (chemical vapor deposition) or PVD (physical vapor deposition) are used to produce a further layer of the moisture barrier.

In a further preferred embodiment, a third barrier layer and a fourth barrier layer adjoin one another directly. The embodiment as a double barrier layer has proven to be particularly effective for improving the tightness. Thus, the moisture barrier in this embodiment comprises at least two double barrier layers. Further preferably, the moisture barrier contains more than four barrier layers, for example five, six, seven, or eight barrier layers. Preferably, the barrier layers are each arranged such that two barrier layers are always directly adjacent to one another.

A possible preferred sequence of layers in a moisture barrier is:
first barrier layer-second barrier layer-third barrier layer-fourth barrier layer. In this case, there are no polymeric layers, but the barrier layers are arranged directly on the polymeric hollow profile and are preferably all deposited by ALD.

Another preferred sequence of layers in a moisture barrier is:
first barrier layer-second barrier layer-first polymeric layer-third barrier layer-fourth barrier layer-second polymeric layer. This moisture barrier can be produced by lamination of two polymeric layers coated on one side (in this case an adhesive bonding layer would be arranged between the first polymeric layer and the third barrier layer) or alternatively by adhesive bonding of a polymeric layer coated on two sides to a further polymeric layer (in this case, for example, an adhesive bonding layer would be arranged between the fourth barrier layer and the second polymeric layer).

An adhesive bonding layer for adhesively bonding coated or uncoated films to a moisture barrier preferably has a thickness of 1 μm to 8 μm, preferably of 2 μm to 6 μm. This ensures a secure adhesive bond.

In a further preferred embodiment, a barrier layer is exposed as an outer layer on the side of the hollow profile facing away from the cavity. The term “exposed” means that the barrier layer faces the external environment and not the cavity. In the finished insulating glazing, the outer layer is in direct contact with the secondary sealant in the region of the outer wall or with the primary sealant in the region of the side walls. The inorganic barrier layers have a substantially improved adhesion to the sealants compared to a polymeric material. It is therefore advantageous if a barrier layer according to the invention is arranged as the outer layer.

In a preferred embodiment, the outer layer is a barrier layer according to the invention deposited via ALD and is based on silicon oxide (SiOx) or consists of SiOx. SiOx has particularly good adhesion to the materials of the secondary sealant and has low heat conduction, which further improves the thermally insulating properties of the spacer.

In a preferred embodiment, the outer layer is a barrier layer according to the invention deposited via ALD and is based on an oxide of aluminum, titanium, nickel, chromium, or iron. These metal oxides are distinguished by particularly good adhesion to the adjacent sealant. Surprisingly good results were achieved with an outer layer of chromium oxide or titanium oxide.

Two directly adjacent barrier layers have different compositions according to the invention. This means that two directly adjacent barrier layers are based on two different compounds. The embodiment of two different materials leads to an improved seal compared to two layers made of the same material.

In a further preferred embodiment, the thickness of all barrier layers is, in each case, less than 10 nm, preferably between 1 nm and 9 nm, particularly preferably between 2 nm and 8 nm, and very particularly preferably between 3 nm and 7 nm. The application of such thin layers saves material and has excellent tightness thanks to the deposition via ALD.

In a further preferred embodiment, the sum of the thicknesses of all barrier layers is less than 50 nm, preferably less than 40 nm and particularly preferably less than 30 nm. Thanks to the particularly dense barrier layers, only a small total thickness is necessary in order to meet the requirements for a spacer for insulating glazings.

The moisture barrier is preferably arranged continuously in the longitudinal direction of the spacer so that no moisture can penetrate into the inner pane interspace along the entire peripheral spacer frame in the insulating glazing.

The moisture barrier is preferably applied in such a way that the regions of the two side walls adjoining the glazing interior wall are free of moisture barrier. By attaching to the entire outer wall up to the side walls, a particularly good sealing of the spacer is achieved. The advantage of the regions on the side walls that remain free from moisture barrier lies in an improvement of the optical appearance in the installed state. In the case of a moisture barrier which is adjacent to the glazing interior wall, this is visible in the finished insulation glass unit. This is sometimes perceived as aesthetically unattractive. The height of the region that remains free from the moisture barrier is preferably between 1 mm and 3 mm. In this embodiment, the moisture barrier in the finished insulation glass unit is not visible.

In an alternative preferred embodiment, the moisture barrier is attached to the entire side walls. Optionally, the moisture barrier can additionally be arranged on the glazing interior wall. The sealing of the spacer is thus further improved.

The cavity of the spacer according to the invention leads to a reduction in weight compared to a solidly formed spacer and is available for receiving further components, such as a desiccant.

The first side wall and the second side wall represent the sides of the spacer on which the mounting of the outer panes of an insulating glazing takes place when the spacer is installed. The first side wall and the second side wall run parallel to one another.

The outer wall of the hollow profile is the wall that is opposite the glazing interior wall and faces away from the interior of the insulation glass unit (inner pane interspace) in the direction of the outer pane interspace. The outer wall preferably runs substantially perpendicular to the side walls. A planar outer wall, which in its entire course is perpendicular to the side walls (parallel to the glazing interior wall), has the advantage that the sealing surface between spacer and side walls is maximized and that a simpler shaping facilitates the production process.

In a preferred embodiment of the spacer according to the invention, the portions of the outer wall that are closest to the side walls are inclined in the direction of the side walls at an angle α (alpha) of 30° to 60° to the outer wall. This embodiment improves the stability of the polymeric hollow profile. Preferably, the portions closest to the side walls are inclined at an angle α (alpha) of 45°. In this case, the stability of the spacer is further improved. The angled arrangement improves the adhesive bonding of the moisture barrier.

In a preferred embodiment of the spacer according to the invention, the polymeric hollow profile has a substantially uniform wall thickness d. The wall thickness d is preferably in the range from 0.5 mm to 2 mm. In this range, the spacer is particularly robust.

In a preferred embodiment of the spacer according to the invention, the hollow profile contains bio-based polymers, polyethylene (PE), polycarbonates (PC), polypropylene (PP), polystyrene, polyester, polyethylene terephthalate (PET), polyethylene terephthalate glycol (PET-G), polyoxymethylene (POM), polyamides (PA), polyamide-6,6, polybutylene terephthalate (PBT), acrylonitrile butadiene styrene (ABS), acrylic ester styrene acrylonitrile (ASA), acrylonitrile butadiene styrene polycarbonate (ABS/PC), styrene acrylonitrile (SAN), PET/PC, PBT/PC, or copolymers thereof. In a particularly preferred embodiment, the hollow profile consists substantially of one of the listed polymers.

The polymeric hollow profile is preferably glass-fiber-reinforced. Through the selection of the glass fiber content in the polymeric hollow profile, the coefficient of thermal expansion of the polymeric hollow profile can be varied and adjusted. By adjusting the coefficient of thermal expansion of the hollow profile and of the moisture barrier, temperature-induced stresses between the different materials and flaking of the moisture barrier can be avoided. The polymeric hollow profile preferably has a glass fiber content of 20 wt. % to 50 wt. %, particularly preferably 30 wt. % to 40 wt. %. At the same time, the glass fiber content in the polymeric hollow profile improves strength and stability. Glass-fiber-reinforced spacers are generally rigid spacers, which are plugged or welded together from individual straight pieces during assembly of a spacer frame for an insulation glass unit. Here, the connection points must be sealed separately with a sealant in order to ensure optimal sealing of a spacer frame. The spacer according to the invention can be processed particularly well due to the high stability of the moisture barrier and the particularly good adhesion to the sealant.

In an alternative preferred embodiment, the hollow profile does not contain any glass fibers. The presence of glass fibers worsens the thermal insulation properties of the spacer and makes the spacer stiff and brittle. Hollow profiles without glass fibers can be bent better, wherein sealing the connection points is omitted. During bending, the spacer is exposed to particular mechanical loads. In particular in the corners of a spacer frame, the moisture barrier is highly stretched. The structure of the spacer according to the invention with moisture barrier also enables the bending of the spacer without impairing the sealing of the insulation glass unit.

In a further preferred embodiment, the polymeric hollow profile consists of a foamed polymer. In this case, a foaming agent is added during the production of the polymeric hollow profile. Examples of foamed spacers are disclosed in WO2016139180 A1. The foamed embodiment leads to reduced heat conduction through the polymeric hollow profile and a material- and weight-saving compared to a solid polymeric hollow profile.

In a preferred embodiment, the glazing interior wall has at least one perforation. Preferably, a plurality of perforations are formed in the glazing interior wall. The total number of perforations depends on the size of the insulation glass unit. The perforations in the glazing interior wall connect the hollow space to the inner pane interspace of an insulation glass unit, thereby enabling a gas exchange between them. This allows absorption of air moisture by a desiccant located in the cavity and thus prevents the panes from fogging. The perforations are preferably designed as slots, particularly preferably as slots of a width of 0.2 mm and a length of 2 mm. The slots ensure optimal air exchange without desiccant being able to penetrate from the cavity into the inner pane interspace. After production of the hollow profile, the perforations can simply be punched or drilled into the glazing interior wall. The perforations are preferably punched hot into the glazing interior wall.

In an alternative preferred embodiment, the material of the glazing interior wall is porous or embodied with a plastic that is open to diffusion, so that perforations are not required.

The polymeric hollow profile preferably has a width of 5 mm to 55 mm, preferably of 10 mm to 20 mm, along the glazing interior wall. In the sense of the invention, the width is the dimension extending between the side walls. The width is the distance between the surfaces of the two side walls that face away from one another. The distance between the panes of the insulation glass unit is determined through the selection of the width of the glazing interior wall. The exact dimensions of the glazing interior wall depend on the dimensions of the insulation glass unit and the desired pane interspace size.

The hollow profile preferably has a height of 5 mm to 15 mm, particularly preferably of 6 mm to 10 mm, along the side walls. In this height range, the spacer has an advantageous stability but is otherwise advantageously inconspicuous in the insulation glass unit. In addition, the cavity of the spacer has an advantageous size for receiving an appropriate quantity of desiccant. The height of the spacer is the distance between the surfaces of the outer wall and of the glazing interior wall that face away from one another.

The cavity preferably contains a desiccant, preferably silica gels, molecular sieves, CaCl₂, Na₂SO₄, activated carbon, silicates, bentonites, zeolites, and/or mixtures thereof.

Thanks to the structure according to the invention, the spacer offers good sealing against the diffusion of gases from the pane interspace and against the diffusion of moisture into the pane interspace. The spacer according to the invention preferably meets the test standard EN 1279 Parts 2+3.

The invention furthermore comprises an insulation glass unit with at least a first pane, a second pane, a circumferential spacer according to the invention arranged between the first and second panes, an inner pane interspace and an outer pane interspace. The spacer according to the invention is arranged to form a circumferential spacer frame. The first pane is attached to the first side wall of the spacer by means of a primary sealant, and the second pane is attached to the second side wall by means of a primary sealant. This means that a primary sealant is arranged between the first side wall and the first pane and between the second side wall and the second pane. The first pane and the second pane are arranged parallel and preferably congruently. The edges of the two panes are therefore preferably arranged flush in the edge region, i.e., they are located at the same height. The inner pane interspace is delimited by the first and second panes and the glazing interior wall. The outer pane interspace is defined as the space that is delimited by the first pane, the second pane and the moisture barrier on the outer wall of the spacer. The outer pane interspace is at least partially filled with a secondary sealant, wherein the secondary sealant is in direct contact with the moisture barrier. The secondary sealant contributes to the mechanical stability of the insulation glass unit and absorbs a portion of the climate burdens that act on the edge composite.

In a preferred embodiment of the insulation glass unit according to the invention, the primary sealant covers the transition between the polymeric hollow profile and the moisture barrier, so that a particularly good sealing of the insulation glass unit is achieved. In this way, the diffusion of moisture into the cavity of the spacer is reduced at the location where the moisture barrier is adjacent to the plastic (less interface diffusion).

In a further preferred embodiment of the insulation glass unit according to the invention, the secondary sealant is applied along the first pane and the second pane such that a central region of the outer wall is free of secondary sealant. The central region denotes the region arranged centrally in relation to the two outer panes, in contrast to the two outer regions of the outer wall, which are adjacent to the first pane and the second pane. In this way, good stabilization of the insulation glass unit is achieved, wherein material costs for the secondary sealant are saved at the same time. At the same time, this arrangement can be easily produced by applying two strands of secondary sealant to the outer wall in the outer region adjacently to the outer panes.

In a further preferred embodiment, the secondary sealant is applied such that the entire outer pane interspace is completely filled with secondary sealant. This leads to maximum stabilization of the insulation glass unit.

The secondary sealant preferably contains polymers or silane-modified polymers, particularly preferably organic polysulfides, silicones, hot melt, polyurethanes, room-temperature crosslinking (RTV) silicone rubber, peroxide-crosslinked silicone rubber and/or addition-crosslinked silicone rubber. These sealants have a particularly good stabilizing effect. With the spacer according to the invention, excellent adhesion results were achieved by virtue of the adhesive layer for the entire spectrum on customary secondary sealants.

The primary sealant preferably contains a polyisobutylene. The polyisobutylene may be a crosslinking or non-crosslinking polyisobutylene.

The first pane and the second pane of the insulation glass unit preferably contain glass, ceramic and/or polymers, particularly preferably quartz glass, borosilicate glass, soda-lime glass, polymethyl methacrylate or polycarbonate.

The first pane and the second pane have a thickness of 2 mm to 50 mm, preferably 3 mm to 16 mm, wherein the two panes may also have different thicknesses.

In a preferred embodiment of the insulation glass unit according to the invention, the spacer frame consists of one or more spacers according to the invention. For example, it may be a spacer according to the invention which is bent to form a complete frame. It may also be a plurality of spacers according to the invention which are linked to one another via one or more plug connectors. The plug connectors may be designed as longitudinal connectors or corner connectors. Such corner connectors may be designed, for example, as a plastic molded part with a seal, in which two spacers provided with a miter cut abut.

In principle, a wide variety of geometries of the insulation glass unit are possible, e.g., rectangular, trapezoidal and rounded shapes. In order to produce round geometries, the spacer according to the invention may, for example, be bent in the heated state.

In a further embodiment, the insulating glazing comprises more than two panes. In this case, the spacer can contain, for example, grooves in which at least one further pane is arranged. A plurality of panes could also be formed as a laminated glass pane.

The statements regarding the spacer according to the invention apply analogously to the insulation glass unit according to the invention. Likewise, the statements regarding the insulation glass unit according to the invention can also be applied to the spacer according to the invention.

The invention furthermore comprises the use of the insulation glass unit according to the invention as building interior glazing, building exterior glazing and/or façade glazing.

The various embodiments of the invention may be implemented individually or in any combinations. In particular, the features mentioned above and explained below can be used not only in the specified combinations but also in other combinations or alone without departing from the scope of the present invention.

The invention is explained in more detail below with reference to drawings. The drawings are purely schematic representations and are not true to scale. They do not restrict the invention in any way. In the figures:

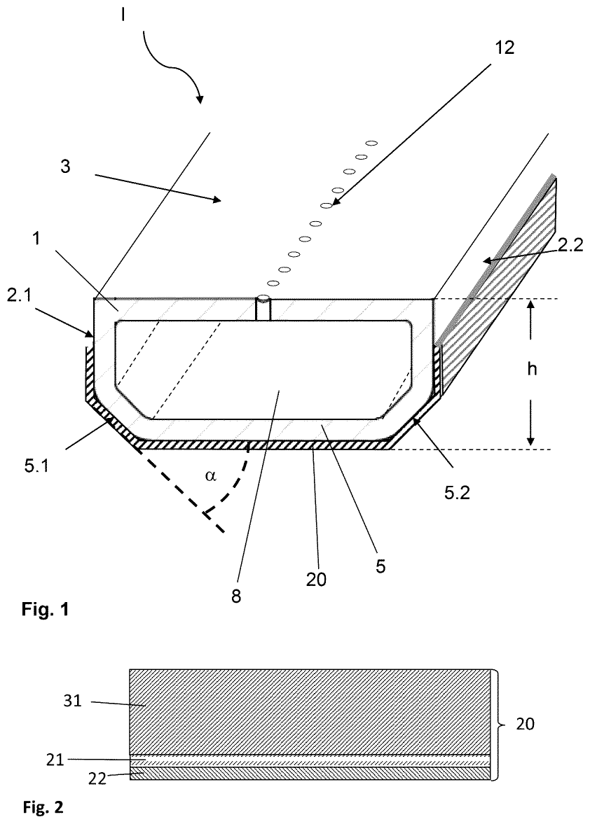

FIG. 1 shows a perspective cross-section of a possible embodiment of a spacer according to the invention,

FIG. 2 shows a cross-section of a possible embodiment of a moisture barrier of a spacer according to the invention,

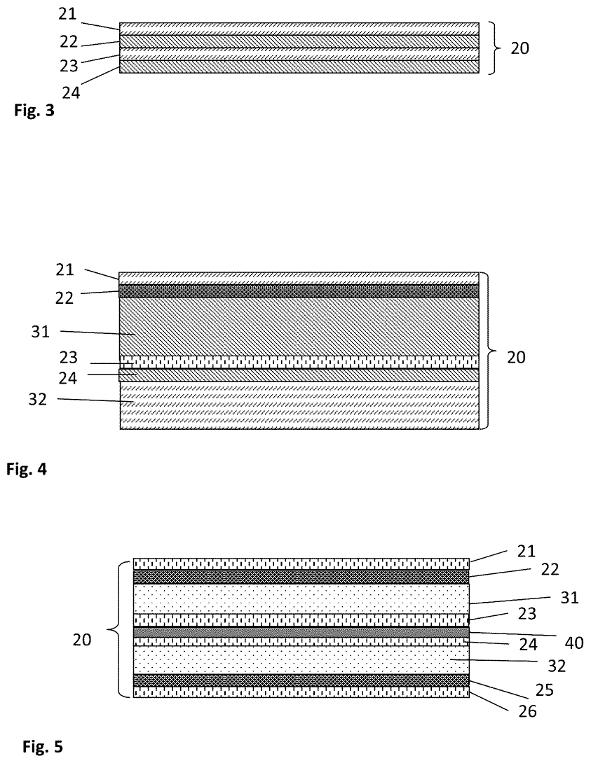

FIG. 3 shows a cross-section of a possible embodiment of a moisture barrier of a spacer according to the invention,

FIG. 4 shows a cross-section of a possible embodiment of a moisture barrier of a spacer according to the invention,

FIG. 5 shows a cross-section of a possible embodiment of a moisture barrier of a spacer according to the invention,

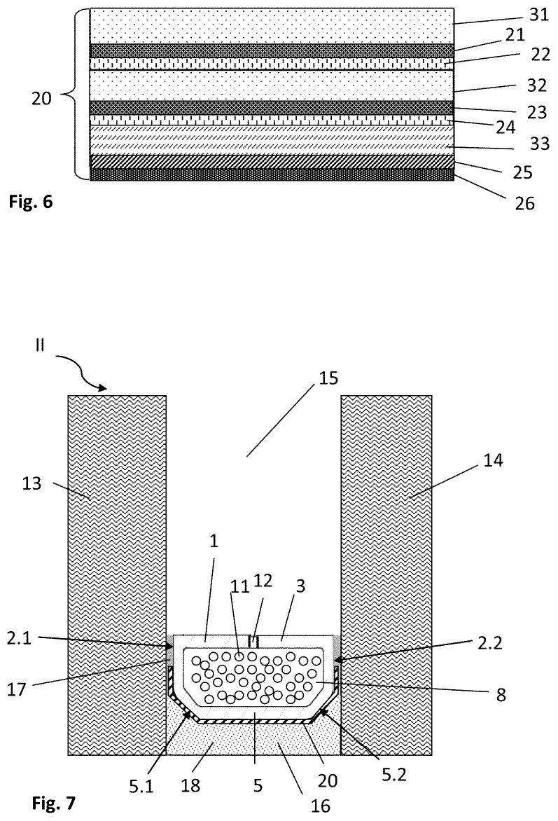

FIG. 6 shows a cross-section of a possible embodiment of a moisture barrier of a spacer according to the invention, and

FIG. 7 shows a cross-section of a possible embodiment of an insulation glass unit according to the invention.

FIG. 1 shows a cross-section through a possible spacer I according to the invention. The spacer comprises a polymeric hollow profile 1 with a first side wall 2.1, a side wall 2.2 running parallel thereto, a glazing interior wall 3, and an outer wall 5. The glazing interior wall 3 runs perpendicularly to the side walls 2.1 and 2.2 and connects the two side walls. The outer wall 5 is opposite the glazing interior wall 3 and connects the two side walls 2.1 and 2.2. The outer wall 5 runs substantially perpendicularly to the side walls 2.1 and 2.2. The portions 5.1 and 5.2 of the outer wall 5 that are closest to the side walls 2.1 and 2.2 are however inclined in the direction of the side walls 2.1 and 2.2 at an angle α (alpha) of about 45° to the outer wall 5. The angled geometry improves the stability of the hollow profile 1 and enables better adhesive bonding with a moisture barrier 20. The hollow profile 1 is a polymeric hollow profile which consists substantially of polypropylene with 20 wt. % glass fibers. The wall thickness of the hollow profile is 1 mm. The wall thickness is substantially the same everywhere. This improves the stability of the hollow profile and simplifies production. The hollow profile 1 has, for example, a height h of 6.5 mm and a width of 15.5 mm. The outer wall 5, the glazing interior wall 3 and the two side walls 2.1 and 2.2 enclose the cavity 8. A moisture barrier 20 is arranged on the outer wall 5 and a part of the first side wall 2.1 and a part of the second side wall 2.2. The regions of the first side wall 2.1 and of the second side wall 2.2 adjoining the glazing interior wall 3 remain free of moisture barrier 20. Measured from the glazing interior wall 3, this is a strip 1.9 mm wide, which remains free. The moisture barrier 20 can, for example, be fastened to the polymeric hollow profile 1 using a polymethacrylate adhesive. Suitable moisture barriers 20 are, for example, the embodiments shown in FIGS. 2 and 4 to 7. Alternatively, the moisture barrier 20 can also be deposited directly on the polymeric hollow profile. In this case, for example, the moisture barrier 20 shown in FIG. 3 is suitable. The moisture barrier 20 is preferably arranged on the entire side walls 2.1 and 2.2 because this can be produced particularly easily in the case of direct coating by means of atomic layer deposition. The cavity 8 can receive a desiccant 11. Perforations 12, which produce a connection to the inner pane interspace in the insulation glass unit, are formed in the glazing interior wall 3. The desiccant 11 can then absorb moisture from the inner pane interspace 15 via the perforations 12 in the glazing interior wall 3 (see FIG. 7).

FIG. 2 shows a cross-section through a moisture barrier 20 of a spacer I according to the invention. The moisture barrier 20 comprises a polymeric layer 31, a first barrier layer 21 and a second barrier layer 22. The polymeric layer 31 is a PET layer 12 μm thick. A titanium oxide layer 21 which is 9 nm thick was then deposited via atomic layer deposition (ALD), and an aluminum oxide layer 22 which is 9 nm thick was likewise deposited directly via atomic layer deposition (ALD). The two barrier layers 21 and 22 are based on different materials, which has proven to be particularly advantageous for the tightness of the moisture barrier 20. In spite of the thin barrier layers 21 and 22, the moisture barrier 20 has good tightness. A corresponding measurement for determining the water vapor permeability of the film yielded a significantly improved WVTR (water vapor transmission rate) compared to a PET film 12 μm thick and coated by means of CVD with an aluminum layer approximately 80 nm thick, despite the overall thicker barrier layer. Both values were measured under the same conditions. Thus, the application of two thin oxidic barrier layers via ALD has a significant improvement compared to a thicker metallic barrier layer. In addition, the heat conduction through the two thin oxidic layers is lower than by the thicker elemental metallic barrier layer, which improves the thermally insulating properties of the spacer according to the invention without elemental metallic layers. The moisture barrier 20 is preferably applied in such a way that the polymeric layer 31 points to the outer wall 5 of the polymeric hollow profile 1. The moisture barrier is then attached to the outer wall 5, for example via an acrylate adhesive. In this case, the second barrier layer 22 made of aluminum oxide is the outer layer and, in the finished insulation glass unit, faces the outer pane interspace and is in direct contact with the secondary sealant. Since the aluminum oxide layer has good adhesion to the usual secondary sealants, this arrangement is advantageous. The long-term stability of the insulation glass unit is thus further improved.

FIG. 3 shows a cross-section through a further moisture barrier 20 of a spacer I according to the invention. The shown moisture barrier 20 comprises exclusively barrier layers, which are applied via ALD. In this case, the first barrier layer 21 made of silicon oxide is applied directly to the polymeric hollow profile 1 via ALD. This is followed directly by the second barrier layer 22 made of chromium oxide. In addition, a layer of silicon oxide 23 and a layer of chromium oxide 24 are arranged again. In this case, the outer layer is the fourth barrier layer 24 made of chromium oxide, which has particularly good adhesion to the secondary sealing material. All layers are 7 nm thick, resulting in a total thickness of the barrier layers of less than 30 nm. This is a particularly material-saving embodiment, wherein the sealing is provided by the arrangement of several thin and particularly dense barrier layers.

FIG. 4 shows a cross-section through a further moisture barrier 20 of a spacer I according to the invention. The fastening to the outer wall 5 of the spacer is achieved advantageously via an adhesive. The moisture barrier 20 comprises two polymeric layers 31, 32, wherein the first polymeric layer 31 is a PET layer 12 μm thick and the second polymeric layer 32 is an oPET layer 12 μm thick. The oPET layer is the polymeric layer arranged further in the direction of the outer pane interspace. This layer is subject to higher loads during the processing of the spacer, such as, for example, during bending. Therefore, a particularly resistant oriented film is used here to improve the mechanical load-bearing capacity of the spacer. The first polymeric layer 31 is coated with the second barrier layer 22 made of titanium nitride (5 nm) and the first barrier layer 21 made of silicon nitride (5 nm) via ALD. The fourth barrier layer 24 is made of silicon oxide (5 nm), the third barrier layer 23 made of aluminum oxide (5 nm). The moisture barrier 20 can be produced by lamination of two coated polymeric layers. In this case, an adhesive bonding layer which is not shown in the drawing can be arranged between the first polymeric layer 31 and the third barrier layer 23. Thanks to the two polymeric layers and the total of four barrier layers, the moisture barrier particularly efficiently prevents the diffusion of water into the inner pane interspace. In particular, the arrangement of the barrier layers as “double layers,” that is to say, in each case two barrier layers directly adjoin one another, has proven to be advantageous.

FIG. 5 shows a cross-section through a moisture barrier 20 of a spacer I according to the invention. The moisture barrier 20 comprises two polymeric layers 31 and 32, each of which consists of oPP (oriented polypropylene) 12 μm thick. Both oPP layers are coated double-sidedly with two barrier layers each on the exposed side and one barrier layer on the inner side facing the adhesive bonding layer 40. The first, third, fourth and sixth barrier layers 21, 23, 24 and 26 are each silicon oxide layers 4 nm thick and the second and fifth barrier layers 22 and 25 are each zirconium oxide layers 4 nm thick. Due to the plurality of layers, this moisture barrier is particularly dense. The outer layers 21 and 26 are silicon oxide layers and adhere very well to the secondary sealant. Due to the symmetrical structure of the moisture barrier, the film can be produced by adhesively bonding two double-sidedly coated oPP layers via a bonding layer 40 3 μm thick made of a polyurethane adhesive.

FIG. 6 shows a cross-section through a further embodiment of a moisture barrier 20 according to the invention. The moisture barrier comprises three polymeric layers 31, 32 and 33, as well as a total of six barrier layers 21, 22, 23, 24, 25 and 26. The six barrier layers are arranged in three blocks, wherein the layers 21 and 22, the layers 23 and 24, and the layers 25 and 26 are each deposited directly on one another via ALD. The arrangement as twofold barrier layers has proven to be particularly advantageous. The first polymeric layer 31 is a PET layer 12 μm thick, the second polymeric layer 32 is a PET layer 12 μm thick, and the third polymeric layer 33 is a boPP layer 16 μm thick. The first barrier layer 21 and the third barrier layer 23 are each titanium oxide layers 5 nm thick. The second barrier layer 22 and the fourth barrier layer 24 are each aluminum oxide layers (5 nm). The fifth barrier layer 25 is a silicon oxide layer (5 nm) 5 nm thick and the barrier layer 26 provided as an outer layer is a chromium oxide layer (5 nm) and improves the adhesion to the secondary sealant.

FIG. 7 shows a cross-section of the edge region of an insulation glass unit II according to the invention with the spacer I shown in FIG. 1. The first pane 13 is connected to the first side wall 2.1 of the spacer I by means of a primary sealant 17, and the second pane 14 is attached to the second side wall 2.2 by means of the primary sealant 17. The primary sealant 17 is essentially a crosslinking polyisobutylene. The inner pane interspace 15 is located between the first pane 13 and the second pane 14 and is delimited by the glazing interior wall 3 of the spacer I according to the invention. The inner pane interspace 15 is air-filled or filled with an inert gas, such as argon. The cavity 8 is filled with a desiccant 11, for example a molecular sieve. The cavity 8 is connected to the inner pane interspace 15 via perforations 24 in the glazing interior wall 3. Through the perforations 24 in the glazing interior wall 3, a gas exchange takes place between the cavity 8 and the inner pane interspace 15, wherein the desiccant 11 absorbs the air moisture from the inner pane interspace 15. The first pane 13 and the second pane 14 project beyond the side walls 2.1 and 2.2 so that an outer pane interspace 16 is produced, which is located between the first pane 13 and the second pane 14 and is delimited by the outer wall 5 with the moisture barrier 20 of the spacer I. The edge of the first pane 13 and the edge of the second pane 14 are arranged at the same height. The outer pane interspace 16 is filled with a secondary sealant 18. The secondary sealant 18 in the example is a polysulfide. Polysulfides absorb the forces acting on the edge composite particularly well and thus contribute to high stability of the insulation glass unit II. The adhesion of polysulfides to the adhesive layer of the spacer according to the invention is excellent. The first pane 13 and the second pane 14 consist of soda-lime glass of a thickness of 3 mm.

### LIST OF REFERENCE SIGNS

I Spacer
II Insulation glass unit
1 Hollow profile
2.1 First side wall
2.2 Second side wall
3 Glazing interior wall
5 Outer wall
5.1, 5.2 The portions of the outer wall that are closest to the side walls
8 Cavity
11 Desiccant
12 Perforation in the glazing interior wall
13 First pane
14 Second pane
15 Inner pane interspace
16 Outer pane interspace
17 Primary sealant
18 Secondary sealant
20 Moisture barrier
21 First barrier layer
22 Second barrier layer
23 Third barrier layer
24 Fourth barrier layer
25 Fifth barrier layer
26 Sixth barrier layer
31 (First) polymeric layer
32 Second polymeric layer
33 Third polymeric layer
40 Internal adhesive bonding layer

1. A spacer for insulation glass units, comprising:
a polymeric hollow profile comprising
a first side wall and a second side wall arranged parallel thereto, a glazing interior wall connecting the side walls to one another;
an outer wall arranged substantially parallel to the glazing interior wall and connecting the first and second side walls to one another;
a cavity enclosed by the first and second side walls, the glazing interior wall and the outer wall,
a moisture barrier on the first side wall, the outer wall and on the second side wall of the polymeric hollow body, wherein the moisture barrier comprises
a first barrier layer and a directly adjacent second barrier layer which are both deposited via atomic layer deposition,
the first barrier layer and the second barrier layer each have a thickness of at most 15 nm,
the first barrier layer and the second barrier layer are based independently of one another on a nitride, oxidic, sulfidic or fluoridic compound.

2. The spacer for insulation glass units according to claim 1, wherein the first barrier layer is applied directly to the polymeric hollow profile.

3. The spacer for insulation glass units according to claim 1, wherein the moisture barrier is attached in the form of a film to the polymeric hollow profile via an adhesive and the moisture barrier comprises at least one polymeric layer.

4. The spacer for insulation glass units according to claim 1, wherein the moisture barrier does not comprise barrier layers based on an elemental metal.

5. The spacer for insulation glass units according to claim 1, wherein the polymeric layer comprises polyethylene terephthalate, polyvinylidene chloride, polyamides, polyethylene, polypropylene, oriented polypropylene, biaxially oriented polypropylene, oriented polyethylene terephthalate, biaxially oriented polyethylene terephthalate.

6. The spacer for insulation glass units according to claim 1, wherein the polymeric layer or all polymeric layers has/have a thickness of 5 μm to 50 μm.

7. The spacer for insulation glass units according to claim 1, wherein the moisture barrier does not contain a polymeric layer made of ethylene vinyl alcohol (EVOH).

8. The spacer for insulation glass units according to claim 1, wherein the moisture barrier contains at least three barrier layers.

9. The spacer for insulation glass units according to claim 1, wherein all barrier layers are deposited via atomic layer deposition and are based independently of one another on a nitride, oxidic, sulfidic, or fluoridic compound.

10. The spacer for insulation glass units according to claim 8, wherein a third barrier layer and a fourth barrier layer directly adjoin one another.

11. The spacer for insulation glass units according to claim 1, wherein a barrier layer is exposed as an outer layer on the side of the hollow profile facing away from the cavity.

12. The spacer for insulation glass units according to claim 1, wherein a sum of thicknesses of all barrier layers is less than 50 nm.

13. The spacer for insulation glass units according to claim 1, wherein a thickness of the barrier layers is less than 10 nm.

14. An insulation glass unit, at least comprising a first pane a second pane, and a spacer according to claim 1, arranged peripherally between the first pane and the second pane, wherein
the first pane is attached to the first side wall by a primary sealant,
the second pane is attached to the second side wall by a primary sealant,
an inner pane interspace is delimited by the glazing interior wall, the first pane and the second pane,
an outer pane interspace is delimited by the moisture barrier mounted on the outer wall and by the first pane and the second pane,
a secondary sealant is arranged in the outer pane interspace, wherein the secondary sealant is in contact with the moisture barrier.

15. A method comprising providing an insulation glass unit according to claim 14 as a building interior glazing, building exterior glazing and/or façade glazing.

16. The spacer for insulation glass units according to claim 3, wherein the moisture barrier comprises at least two polymeric layers.

17. The spacer for insulation glass units according to claim 6, wherein the polymeric layer or all polymeric layers has/have a thickness of 10 μm to 35 μm.

18. The spacer for insulation glass units according to claim 8, wherein the moisture barrier contains at least four barrier layers.

19. The spacer for insulation glass units according to claim 12, wherein the sum of the thicknesses of all barrier layers is less than 40 nm.

20. The spacer for insulation glass units according to claim 13, wherein the thickness of the barrier layers is between 2 nm and 8 nm.
